(19) United States
(12) Patent Application Publication
(10) Pub. No.: US 2026/0293718 A1
(43) Pub. Date: Sep. 24, 2026

(54) METHOD OF MANUFACTURING AN IPD-TYPE ELECTRONIC DEVICE

(71) Applicant: STMICROELECTRONICS INTERNATIONAL N.V., Geneva (CH)

(72) Inventor: Ludovic FALLOURD, Louans (FR)

(21) Appl. No.: 19/559,079

(22) Filed: Mar. 6, 2026

(30) Foreign Application Priority Data
Mar. 20, 2025 (FR) 2502866

(51) Int. Cl. H10W 70/63; H10W 70/05; H10W 70/652; H10W 44/00; H10W 70/698

(52) U.S. Cl. CPC H10W 70/635; H10W 70/095; H10W 70/6528; H10W 44/401; H10W 44/501; H10W 44/601; H10W 70/698

(57) ABSTRACT

The present disclosure provides a method of manufacturing an Integrated Passive Devices (IPD) electronic device. An example method includes the steps of: a) providing a structure with: a substrate having a resistivity higher than 1 kΩ/cm, passive components being formed inside or on top of a first surface of the substrate, and an interconnection structure covering the first surface of the substrate and comprising a dielectric material in which are formed electrically-conductive tracks and connection areas; b) from a second surface of the substrate, forming a via extending so as to reach an electrically-conductive track electrically connected to one of the connection areas or to reach one of the connection areas; c) filling the via with a solderable material; and d) performing a reflow to melt the solderable material and form a connection pad.

### CROSS REFERENCE TO RELATED APPLICATIONS

This application claims the priority benefit of French Patent Application Number FR2502866, filed on Mar. 20, 2025, entitled “PROCÉDÉ DE FABRICATION D'UN DISPOSITIF ÉLECTRONIQUE DE TYPE IPD”, which is hereby incorporated by reference to the maximum extent allowable by law.

### TECHNICAL FIELD

The present disclosure generally concerns the field of microelectronics and, more particularly, that of devices comprising passive components (generally designated by trade name "IPD" for "Integrated Passive Devices").

### BACKGROUND

Interposers are electronic devices enabling to form physical and electrical bridges between different elements, for example between one or a plurality of electronic chips and a printed circuit board (PCB).

IPD interposers integrate passive components (resistors, capacitors, and/or inductance coils) within their structure.

There exists a need to decrease the size of IPD interposers and to be able to integrate them in 3D architectures while keeping a good electrical efficiency.

### BRIEF SUMMARY

There exists a need to have a method of manufacturing an IPD-type electronic device, compact and which can be connected on its two main surfaces.

This object is achieved by a method of manufacturing an electronic device of IPD type, comprising the following steps:
a) providing a structure comprising: an interconnection structure covering the first surface of the substrate and the passive components, the interconnection structure comprising a dielectric material in which are formed electrically-conductive tracks and connection areas, the connection areas being covered by connection pads,
b) from the second surface of the substrate, forming a via to reach an electrically-conductive track electrically connected to one of the connection areas or to reach one of the connection areas, a substrate having a resistivity higher than 1 kΩ/cm, preferably made of glass or of high-resistivity silicon, passive components being formed in the substrate or on a first surface of the substrate,
c) filling the via with a solderable material, d) performing a reflow to melt the solderable material and form a connection pad emerging from the second surface of the substrate.

According to a specific embodiment, between step b) and step c), a seed layer is deposited on the walls of the via.

According to a specific embodiment, during step d), the temperature is higher than the melting temperature of the seed layer, whereby during step d), the seed layer melts and mixes with the solderable material.

According to a specific embodiment, wherein during step d), the temperature is lower than the melting temperature of the seed layer, whereby the seed layer covers the walls of the via at the end of step d).

According to a specific embodiment, the seed layer is made of titanium, gold, silver, copper, or one of their alloys.

According to a specific embodiment, the solderable material is made of tin or of a tin-based alloy, for example of an AuSn or SnAgCu alloy.

According to a specific embodiment, a plurality of vias are formed during step b), each via being filled with the solderable material during step c), whereby a plurality of connection pads is formed during step d).

This object is also achieved by an electronic device of IPD type comprising:

a substrate having a resistivity higher than 1 kΩ/cm, passive components being formed in the substrate or on a first surface of the substrate,- an interconnection structure covering the first surface of the substrate and the passive components, the interconnection structure comprising a dielectric material in which are formed electrically-conductive tracks and connection areas, the connection areas being covered by connection pads,

a via starting from the second surface of the substrate to reach an electrically-conductive track electrically connected to one of the connection areas or to reach one of the connection areas,

a connection pad filling the via and emerging from the second surface of the substrate.

According to a specific embodiment, the seed layer covers the walls of the via.

According to a specific embodiment, the seed layer is made of titanium, gold, silver, copper, or one of their alloys.

According to a specific embodiment, the substrate is made of glass or of high-resistivity silicon.

This object is also achieved by an assembly comprising an electronic device of IPD type, such as defined in one of claims 8 to 11, assembled:

on the one hand, by the connection pads positioned on the connection areas of the interconnection structure to a first external device, for example a support, in particular a printed circuit board, and

on the other hand, by the connection pads emerging from the second surface of the substrate to a second external device, for example an electronic chip.

This object is also achieved by the use of such an electronic device or of such an electronic assembly in an automobile, for example in an advanced driver assistance system, in personal electronics, in communications equipment, such as a computer, a smartphone, a connected object (IoT), or one of their peripherals.

This object is also achieved by an automobile, communications equipment, such as a computer, a smartphone, a connected object (IoT), or one of their peripherals comprising such an electronic device or such an electronic assembly.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, FIG. 1C, FIG. 1D, and FIG. 1E schematically show different steps of a method of manufacturing an IPD-type electronic device, according to a specific embodiment of the present disclosure;

FIG. 2 and FIG. 3 show, schematically and in cross-section, IPD-type electronic devices, according to different specific embodiments of the present disclosure;

FIG. 4 show, schematically and in cross-section, an assembly integrating an IPD-type electronic device, a first external device, such as a PCB, and a second external device such as an electronic chip, according to another specific embodiment.

The different elements are not necessarily shown to a uniform scale in order to make the drawings more readable.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as "front", "back", "top", "bottom", "left", "right", etc., or relative position qualifiers, such as "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10%, preferably of plus or minus 5%.

By in the range from X to Y, there is meant that limits X and Y are included.

The method which will be described in further detail hereafter is a method of manufacturing an electronic device 1000 of IPD type, for example an IPD die. Such devices 1000 integrate passive components within their structure and plays the role of an interposer between different external devices 1100, 1200, for example, between a die and a substrate. They enable to manufacture compact 3D modules 5000.

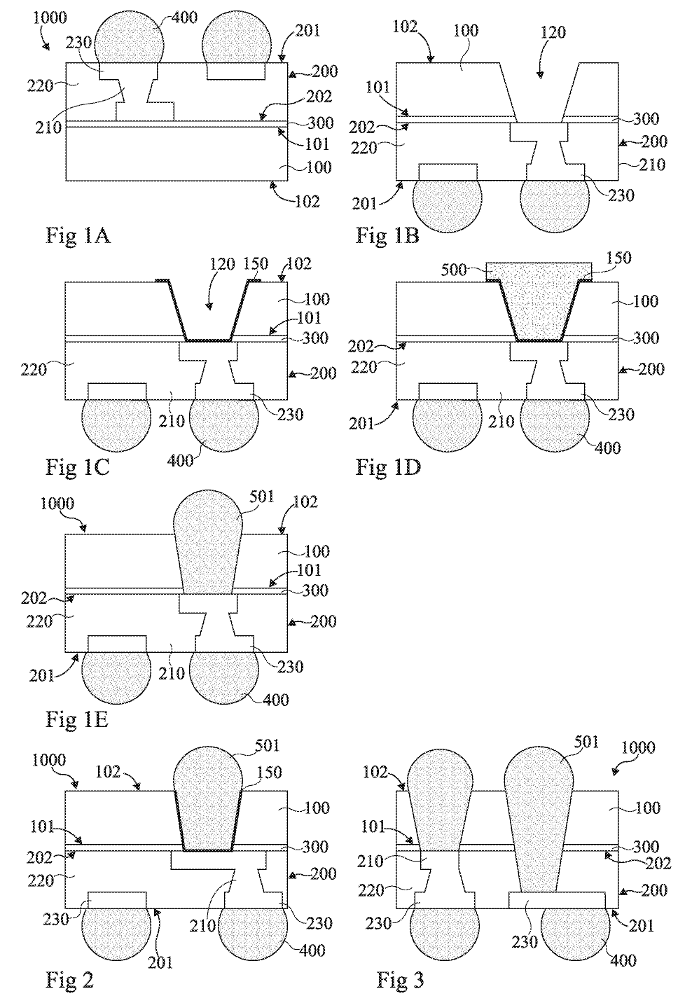

As shown in FIGS. 1A to 1E, the method comprises at least the following steps:

a) providing a structure comprising (FIG. 1A):

an insulating substrate 100, preferably made of glass or of high-resistivity silicon, comprising a first main surface 101 and a second main surface 102, passive components being formed in substrate 100 or on the first main surface 101 of substrate 100,

an interconnection structure 200 formed of a dielectric material 220 in which are formed electrically-conductive tracks 210 and interconnection areas 230, connection areas 230 emerging onto the first surface 101 of substrate 100 and being connected to electrically-conductive tracks 210,

preferably, connection pads 400 covering connection areas 230,

b) from the second surface 102 of substrate 100, forming a through via 120 to reach an electrically-conductive track 210 electrically connected to one of connection areas 230 (FIG. 1B) or to reach a connection area 230,

preferably, forming a seed layer 150 on the walls and the bottom of via 120 (FIG. 1C),

c) filling via 120 with a solderable material 500 (FIG. 1D),

d) performing a reflow to melt solderable material 500 and form connection pads 501 (FIG. 1E).

The method implements a step of forming of vias 120 from the back side 102 of component 100 and a step of metallization of vias 120 with a solderable material 500.

Vias 120 are formed, for example, by laser etching and/or chemical etching (e.g., using a Bosch-type process). Vias 120 cross the entire thickness of substrate 100 to reach interconnection structure 230. Vias 120 are formed so as to provide access to a track 210 of interconnection structure 200 or a connection area 230 of interconnection structure 200. Vias 120 do not cross the entire thickness of interconnection structure 200. The mechanical strength of electronic device 1000 is improved.

The steps of the method are simplified and production costs are decreased.

The integrated passive devices (IPD) obtained by this method may be connected on the front side and on the back side due to the connections which have run up to the back side. These two-faced interconnection devices also offer a wide range of possibilities as to the arrangement of the external devices and of their interconnectivities.

The obtained IPD devices have decreased sizes. The packaging is thus denser, which favors the developing of smaller and more powerful devices. The efficiency and the profitability of the integration of 3D modules is thus improved. Further, its scalability and its flexibility enable it to easily adapt to various applications.

The different steps of the method will now be described in further detail.

The substrate 100 provided at step a) comprises a first main surface (upper surface or front side) 101 and a second main surface (lower surface or back side) 102. The first main surface 101 and the second main surface 102 are coupled together by a lateral surface. The two main surfaces 101, 102 are parallel or substantially parallel to each other. The distance between the two main surfaces 101, 102 corresponds to the thickness of substrate 100. Substrate 100 has, for example, a thickness in the range from 100 to 900 µm, preferably from 300 to 900 µm, for example a thickness of approximately 725 µm.

Substrate 100 is a high insulative substrate. It has, for example, a resistivity higher than 1 kΩ/cm. It is, for example, a substrate made of high-resistivity silicon (HRSI) or made of glass. Any other electrically-insulating substrate or with a high electrically-insulating power may be used.

During step a), one or a plurality of passive components, not shown, have been integrated inside or on top of substrate 100. The passive component(s) are selected from among one or a plurality of the following components: resistors, capacitors, and inductances. This enables to implement different passive electronic functions. The components may be manufactured by methods of deposition or etching at a microscopic scale.

Device 1000 also comprises routing tracks (not shown) for connecting the different components to one another and/or conveying electric signals between two external devices (between a chip and a printed circuit board for example).

According to an embodiment, at this stage of the procedure, substrate 100 corresponds to a wafer and comprises a plurality of electronic devices. The wafer will be cut at the end of the method to separate the different electronic devices from one another. To facilitate the understanding of the drawings, a single electronic device 1000 is shown in the drawings.

An insulating layer 300 may cover the first surface 101 of substrate 100. For example, it may be an oxide layer, in particular an undoped silicate glass layer (USG). It has, for example, a thickness in the range from 0.5 to 3 µm.

The first surface 101 of substrate 100 is covered with an interconnection structure 200. Insulating layer 300 is arranged between substrate 100 and interconnection structure 200.

Interconnection structure 200 comprises one or a plurality of (two or three for example) levels of conductive tracks 210 arranged in an insulating material 220.

Conductive tracks 210 are, for example, of one or a plurality of the materials selected from among copper, a copper alloy, titanium, a titanium alloy, titanium nitride, gold, tungsten, platinum, and a platinum alloy. It may also be aluminum. According to an embodiment, the thickness of each metal track 210 is in the range from 2 to 40 µm, for example from 2 to 12 µm.

Insulating material 220 may be a multilayer formed of a plurality of insulating layers (so-called passivation layers). According to an embodiment, the thickness of each insulating layer is in the range from 0.5 µm to 15 µm.

Insulating material 220 may be organic. Insulating material 220 may be a polymer, in particular BCB (benzo cyclo butene), PI (polyimide) or polybenzoxazole. It may also be a low temperature curing (LTC) polymer, for example based on silicone. A BCB/LTC/PI multilayer may be used, for example.

Interconnection structure 200 comprises a first surface (or upper surface) 201, a second surface 202 (or lower surface) and sides. The second surface 202 of interconnection structure 200 is in contact with the first surface 101 of substrate 100 or with the insulating layer 300 covering the first surface 101 of substrate 100.

Metal tracks 210 are flush with the first surface 201 to form connection areas 230. Connection areas 230 (also called electrical contacts) enable to connect device 1000 to other elements (chips or printed circuit boards for example).

Electrical connection areas 230 are also called "UBM" (for "Under Bump Metallization"). Preferably, there are at least two connection areas 230 on the front side of electronic device 1000.

Electrical connection areas 230 are, for example, at a distance from 10 to 30 µm from the lateral wall of electronic device 1000. This distance depends on the dimensions of electronic device 1000. It may range up to several hundred micrometers or even to one millimeter, depending on electronic device 1000.

Connection pads 400 are bonded to connection areas 230. Connection pads 400 are, advantageously, soldered to electrical connection areas 230. Connection pads 400 are formed of an electrically conductive and "wettable" (that is, solderable or weldable) material, that is, a material on which a soldering can be carried out. For example, pads 400 are made of a tin-based solderable material, typically SnAgCu or CuSnAg.

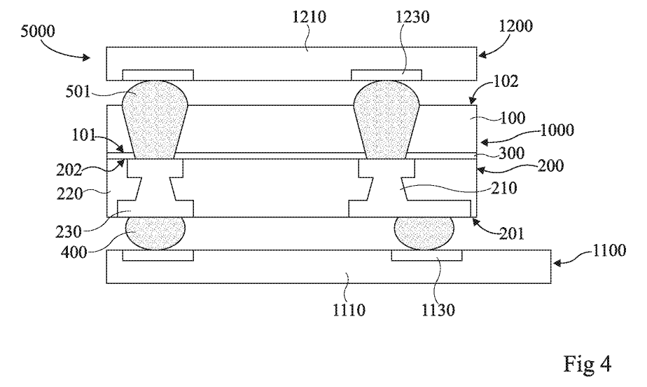

During step b), vias 120 are formed in electronic device 1000. Vias 120 cross substrate 100 and insulating layer 300 when it is present. They may stop at the second surface 202 of interconnection structure 200 (FIG. 1E, FIG. 2, and FIG. 3) or cross a portion of interconnection structure 200 (FIG. 4). Vias 120 do not thoroughly cross interconnection structure 200. The depth of vias 120 will depend on the layout of metal tracks 210 in interconnection structure 200. Each via 120 is formed so as to come into contact with one of tracks 210 connected to one of connection areas 230.

Vias 120 may be arranged opposite connection areas 230 or offset with respect to connection areas 230.

Vias 120 are formed by etching, for example by laser etching.

Before implementing step c), the method comprises, preferably, a step during which a seed layer 150 (also called bonding layer or wettability layer) is deposited into vias 120. It improves the wettability upon deposition of the solder material during step c) and avoids coalescence phenomena. The bonding of solder material 500 to the sides of vias 120 is improved. Seed layer 150 covers the bottom of vias 120 and the lateral walls of vias 120. It may also locally cover the second surface 102 of substrate 100, at the periphery of vias 120. It is made of an electrically-conductive material. It is, for example, made of titanium, silver, gold, or one of their alloys (for example of an alloy of titanium and copper). It has a thickness, for example, in the range from 0.5 to 3 µm. It can be deposited, for example, by physical vapor deposition (PVD), spraying, or autocatalytic deposition (‘electroless plating’).

It is also possible to deposit a passivation layer, for example made of a dielectric material, on the sides of via 120 before depositing solder material 500 or before depositing seed layer 150.

During step c), solder material 500 is deposited into vias 120. Preferably, it totally fills vias 120. For example, it fills vias 120 and may overflow from via 120 to locally cover the second surface 102 of substrate 100, at the periphery of vias 120. Solder material 500 is, for example, made of tin or of a tin alloy, for example of Ag/Sn/Cu or AuSn. Solder material 500 may be deposited by screen printing or any other suitable deposition process.

During step d), a reflow step is carried out. It enables to melt solder material 500 and to form pads 501. Pads 501 emerge from the second surface 102 of substrate 100 to form bumps. The assembly to an external device is thus facilitated.

This step is, for example, carried out at a temperature in the range from 217 to 320 °C. The temperature selected will depend on the alloy/material used.

During this step d), according to the materials used and to the implemented temperature, seed layer 150 may melt and mix with the solder material (FIG. 1E, FIG. 3) or not melt and remain present at the end of the method (FIG. 2).

During the method, for example, after step d), as previously indicated, it is possible to carry out a cutting step to separate the different electronic devices 1000 when they are formed in a same wafer.

The obtained electronic device 1000 may be assembled to a first external device 1100, at the location of the connection pads 400 present on the connection areas 230 of interconnection structure 200, and to a second external device 1200 at the location of the connection pads 501 formed on the second surface 102 of substrate 100.

The assembly method comprises a step of soldering between the connection pads 400, 501 of IPD electronic device 1000 and the connection areas 1130, 1230 of external devices 1100, 1200.

External devices 1100, 1200 (for example the chips) may be assembled by the ’flip-chip’ technique onto IPD device 100.

The first external device 1100 and the second external device 1200 are selected independently from each other, for example, from among a package, a printed circuit board (or PCB), another electronic component, a laminated substrate, an electronic chip, another integrated passive device (IPD), or also an integrated passive and active device (IPAD), or any other component that works in proximity to an IPD.

For example, as shown in FIG. 4, the first external device 1100 is a printed circuit board. It comprises, for example, a support 1110 having connection areas 1130 formed thereon. Conductive tracks (not shown) are formed in support 1110. Connection areas 1130 and the tracks may be made of copper.

For example, as shown in FIG. 4, the second external device 1200 is a chip, for example of CSP (‘Chip Scale Package’) type. It comprises a substrate 1210 having the chip (not shown) formed therein. The substrate is covered by connection areas 1230.

The obtained assembly, formed of IPD-type device 1000 and of external elements 1110, 1200, has an easily adjustable architecture 3D.

Such IPD-type electronic devices 1000 apply in many industrial domains, and in particular in that of RF and wireless devices, of advanced microelectronics, of automobile and aerospace.

They may, for example, be intended for the automotive industry (in particular for advanced driver assistance systems (ADAS)), in the field of the Internet of Things and of smart homes. They may be used in near-field communications (or NFC), or also in the implementation of 5G networks, of data centers, and of servers.

They may be, for example, intended to be used in personal electronics, in 5G connection devices, or more generally in connected devices, in communications equipment, or in computers and peripherals. They enable in particular to protect devices against electrostatic discharges.

They may also be advantageous in other domains, such as for example for the industrial field, in particular for green energies.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an electronic device of Integrated Passive Devices (IPD) type, wherein the method comprises steps of:
a) providing a structure comprising:
a substrate having a resistivity higher than 1 kΩ/cm with passive components being formed in the substrate or on a first surface of the substrate,
an interconnection structure covering the first surface of the substrate and the passive components, the interconnection structure comprising a dielectric material in which are formed electrically-conductive tracks and connection areas, and the connection areas being covered by connection pads;
b) from a second surface of the substrate, forming a via to reach an electrically-conductive track electrically connected to one of the connection areas or to reach one of the connection areas;
c) filling the via with a solderable material; and
d) performing a reflow to melt the solderable material and form a connection pad emerging from the second surface of the substrate.

2. The method of manufacturing an electronic device of IPD type of claim 1, wherein between step b) and step c), a seed layer is deposited on walls of the via.

3. The method of manufacturing an electronic device of IPD type of claim 2, wherein during step d), a temperature is higher than a melting temperature of the seed layer, and wherein during step d), the seed layer melts and mixes with the solderable material.

4. The method of manufacturing an electronic device of IPD type of claim 2, wherein during step d), a temperature is lower than a melting temperature of the seed layer, and wherein the seed layer covers walls of the via at an end of step d).

5. The method of manufacturing an electronic device of IPD type of claim 2, wherein the seed layer is made of titanium, gold, silver, copper, or an alloy of titanium, gold, silver, copper.

6. The method of manufacturing an electronic device of IPD type of claim 1, wherein the solderable material is made of tin or of a tin-based alloy.

7. The method of manufacturing an electronic device of IPD type of claim 1, wherein a plurality of vias are formed during step b), each via being filled with the solderable material during step c), and wherein a plurality of connection pads is formed during step d).

8. An electronic device of Integrated Passive Devices (IPD) type comprising:
a substrate having a resistivity higher than 1 kΩ/cm with passive components being formed in the substrate or on a first surface of the substrate;
an interconnection structure covering the first surface of the substrate and the passive components, the interconnection structure comprising a dielectric material in which are formed electrically-conductive tracks and connection areas, and the connection areas being covered by connection pads;
a via starting from a second surface of the substrate to reach an electrically-conductive track electrically connected to one of the connection areas or to reach one of the connection areas; and
a connection pad filling the via and emerging from the second surface of the substrate.

9. The electronic device of IPD type of claim 8, wherein a seed layer covers walls of the via.

10. The electronic device of IPD type of claim 9, wherein the seed layer is made of titanium, gold, silver, copper, or an alloy of titanium, gold, silver, or copper.

11. The electronic device of IPD type of claim 8, wherein the substrate is made of glass or of high-resistivity silicon.

12. An assembly comprising the electronic device of IPD type of claim 8, wherein the assembly is assembled by the connection pads positioned on the connection areas of the interconnection structure to a first external device; and
wherein the assembly is further assembled by the connection pads emerging from the second surface of the substrate to a second external device.

13. The assembly of claim 12, wherein the first external device is a support.

14. The assembly of claim 13, wherein the support is a printed circuit board.

15. The assembly of claim 12, wherein the second external device is an electronic chip.
